(19) United States
(12) Patent Application Publication
(10) Pub. No.: US 2025/0248091 A1
(43) Pub. Date: Jul. 31, 2025

(54) SEMICONDUCTOR DEVICE INCLUDING SUPERLATTICE SOURCE/DRAIN

(71) Applicant: Atomera Incorporated, Los Gatos, CA (US)

(72) Inventors: DANIEL CONNELLY, SAN FRANCISCO, CA (US); DONGHUN KANG, SAN JOSE, CA (US); KEITH DORAN WEEKS, CHANDLER, AZ (US); NYLES WYNN CODY, TEMPE, AZ (US); ROBERT J. MEARS, WELLESLEY, MA (US); MAREK HYTHA, BROOKLINE, MA (US); HIDEKI TAKEUCHI, SAN JOSE, CA (US)

(21) Appl. No.: 19/041,241

(22) Filed: Jan. 30, 2025

Related U.S. Application Data
(60) Provisional application No. 63/626,683, filed on Jan. 30, 2024.

(51) Int. Cl. H10D 62/815; H10D 30/00; H10D 30/01; H10D 62/13

(52) U.S. Cl. CPC H10D 62/8162; H10D 30/019; H10D 30/501; H10D 62/151

(57) ABSTRACT

A semiconductor device may include a substrate, a stack of alternating gate and nanostructure layers above the substrate, and a first superlattice laterally adjacent the stack on a first side thereof and extending from the substrate to an upper surface of the stack to define a first source/drain region. The first superlattice may include a plurality of stacked groups of layers, with each group of layers including a plurality of stacked base semiconductor monolayers defining a base semiconductor portion, and at least one non-semiconductor monolayer constrained within a crystal lattice of adjacent base semiconductor portions. The non-semiconductor monolayers of the first superlattice may be arranged along growth rings extending outwardly from respective adjacent nanostructure layer portions.

### TECHNICAL FIELD

The present disclosure generally relates to semiconductor devices, and, more particularly, to field effect transistors and related methods.

### BACKGROUND

Structures and techniques have been proposed to enhance the performance of semiconductor devices, such as by enhancing the mobility of the charge carriers. For example, U.S. Patent Application No. 2003/0057416 to Currie et al. discloses strained material layers of silicon, silicon-germanium, and relaxed silicon and also including impurity-free zones that would otherwise cause performance degradation. The resulting biaxial strain in the upper silicon layer alters the carrier mobilities enabling higher speed and/or lower power devices. Published U.S. Patent Application No. 2003/0034529 to Fitzgerald et al. discloses a CMOS inverter also based upon similar strained silicon technology.

U.S. Pat. No. 6,472,685 B2 to Takagi discloses a semiconductor device including a silicon and carbon layer sandwiched between silicon layers so that the conduction band and valence band of the second silicon layer receive a tensile strain. Electrons having a smaller effective mass, and which have been induced by an electric field applied to the gate electrode, are confined in the second silicon layer, thus, an n-channel MOSFET is asserted to have a higher mobility.

U.S. Pat. No. 4,937,204 to Ishibashi et al. discloses a superlattice in which a plurality of layers, less than eight monolayers, and containing a fractional or binary or a binary compound semiconductor layer, are alternately and epitaxially grown. The direction of main current flow is perpendicular to the layers of the superlattice.

U.S. Pat. No. 5,357,119 to Wang et al. discloses a Si—Ge short period superlattice with higher mobility achieved by reducing alloy scattering in the superlattice. Along these lines, U.S. Pat. No. 5,683,934 to Candelaria discloses an enhanced mobility MOSFET including a channel layer comprising an alloy of silicon and a second material substitutionally present in the silicon lattice at a percentage that places the channel layer under tensile stress.

U.S. Pat. No. 5,216,262 to Tsu discloses a quantum well structure comprising two barrier regions and a thin epitaxially grown semiconductor layer sandwiched between the barriers. Each barrier region consists of alternate layers of SiO2/Si with a thickness generally in a range of two to six monolayers. A much thicker section of silicon is sandwiched between the barriers.

An article entitled “Phenomena in silicon nanostructure devices” also to Tsu and published online Sep. 6, 2000 by Applied Physics and Materials Science & Processing, pp. 391-402 discloses a semiconductor-atomic superlattice (SAS) of silicon and oxygen. The Si/O superlattice is disclosed as useful in a silicon quantum and light-emitting devices. In particular, a green electroluminescence diode structure was constructed and tested. Current flow in the diode structure is vertical, that is, perpendicular to the layers of the SAS. The disclosed SAS may include semiconductor layers separated by adsorbed species such as oxygen atoms, and CO molecules. The silicon growth beyond the adsorbed monolayer of oxygen is described as epitaxial with a fairly low defect density. One SAS structure included a 1.1 nm thick silicon portion that is about eight atomic layers of silicon, and another structure had twice this thickness of silicon. An article to Luo et al. entitled “Chemical Design of Direct-Gap Light-Emitting Silicon” published in Physical Review Letters, Vol. 89, No. 7 (Aug. 12, 2002) further discusses the light emitting SAS structures of Tsu.

U.S. Pat. No. 7,105,895 to Wang et al. discloses a barrier building block of thin silicon and oxygen, carbon, nitrogen, phosphorous, antimony, arsenic or hydrogen to thereby reduce current flowing vertically through the lattice more than four orders of magnitude. The insulating layer/barrier layer allows for low defect epitaxial silicon to be deposited next to the insulating layer.

Published Great Britain Patent Application 2,347,520 to Mears et al. discloses that principles of Aperiodic Photonic Band-Gap (APBG) structures may be adapted for electronic bandgap engineering. In particular, the application discloses that material parameters, for example, the location of band minima, effective mass, etc., can be tailored to yield new aperiodic materials with desirable band-structure characteristics. Other parameters, such as electrical conductivity, thermal conductivity and dielectric permittivity or magnetic permeability are disclosed as also possible to be designed into the material.

Furthermore, U.S. Pat. No. 6,376,337 to Wang et al. discloses a method for producing an insulating or barrier layer for semiconductor devices which includes depositing a layer of silicon and at least one additional element on the silicon substrate whereby the deposited layer is substantially free of defects such that epitaxial silicon substantially free of defects can be deposited on the deposited layer. Alternatively, a monolayer of one or more elements, preferably comprising oxygen, is absorbed on a silicon substrate. A plurality of insulating layers sandwiched between epitaxial silicon forms a barrier composite.

Despite the existence of such approaches, further enhancements may be desirable for using advanced semiconductor materials and processing techniques to achieve improved performance in semiconductor devices.

### SUMMARY

A semiconductor device may include a substrate, a stack of alternating gate and nanostructure layers above the substrate, and a first superlattice laterally adjacent the stack on a first side thereof and extending from the substrate to an upper surface of the stack to define a first source/drain region. The first superlattice may include a plurality of stacked groups of layers, with each group of layers comprising a plurality of stacked base semiconductor monolayers defining a base semiconductor portion, and at least one non-semiconductor monolayer constrained within a crystal lattice of adjacent base semiconductor portions. The non-semiconductor monolayers of the first superlattice may be arranged along growth rings extending outwardly from respective adjacent nanostructure layer portions.

In some embodiments, the semiconductor device may further include a second superlattice laterally adjacent the stack on a second side thereof and extending from the substrate to the upper surface of the stack to define a second source/drain region. The second superlattice may also include a plurality of stacked groups of layers, with each group of layers comprising a plurality of stacked base semiconductor monolayers defining a base semiconductor portion, and at least one non-semiconductor monolayer constrained within a crystal lattice of adjacent base semiconductor portions. Furthermore, the non-semiconductor monolayers of the second superlattice may be arranged along growth rings extending outwardly from respective adjacent nanostructure layer portions. The first and second source/drain regions may define respective channels for the semiconductor device through the nanostructure layers.

In an example implementation, the alternating gate and nanostructure layers may be vertically stacked above the substrate. In some embodiments, the nanostructure layers may be nanosheets. Furthermore, each gate layer may include a gate electrode, and a gate insulator separating the gate electrode from adjacent nanostructure layers. In an example embodiment, the first source/drain region may include a phosphorous dopant. By way of example, the first source/drain region may have a dopant concentration of at least 1×10²¹/cm³. Also by way of example, the base semiconductor monolayers may comprise silicon, and the non-semiconductor monolayers may comprise oxygen.

### BRIEF DESCRIPTION OF THE DRAWINGS

FIG. 1 is a greatly enlarged schematic cross-sectional view of a superlattice for use in a semiconductor device in accordance with an example embodiment.

FIG. 2 is a perspective schematic atomic diagram of a portion of the superlattice shown in FIG. 1.

FIG. 3 is a greatly enlarged schematic cross-sectional view of another embodiment of a superlattice in accordance with an example embodiment.

FIG. 4 is a schematic cross-sectional diagram of nanosheet transistor including superlattice source and drain regions in accordance with an example embodiment.

FIG. 5 is a flow diagram illustrating an example method for making the semiconductor device of FIG. 4.

### DETAILED DESCRIPTION

Example embodiments will now be described more fully hereinafter with reference to the accompanying drawings, in which the example embodiments are shown. The embodiments may, however, be implemented in many different forms and should not be construed as limited to the specific examples set forth herein. Rather, these embodiments are provided so that this disclosure will be thorough and complete. Like numbers refer to like elements throughout, and prime notation is used to indicate similar elements in different embodiments.

Generally speaking, the present disclosure relates to semiconductor devices having an enhanced semiconductor superlattice therein to provide performance enhancement characteristics. The enhanced semiconductor superlattice may also be referred to as an “MST” layer or “MST technology” in this disclosure.

More particularly, the MST technology relates to advanced semiconductor materials such as the superlattice 25 described further below. In prior work, Applicant theorized that certain superlattices as described herein reduce the effective mass of charge carriers, and that this accordingly leads to higher charge carrier mobility. See, e.g., U.S. Pat. No. 6,897,472, which is hereby incorporate herein in its entirety by reference.

Further development by Applicant has established that the presence of MST layers may advantageously improve the mobility of free carriers in semiconductor materials, e.g., at interfaces between silicon and insulators like SiO₂ or HfO₂. Applicant theorizes, without wishing to be bound thereto, that this may occur due to various mechanisms. One mechanism is by reducing the concentration of charged impurities proximate to the interface, by reducing the diffusion of these impurities, and/or by trapping the impurities so they do not reach the interface proximity. Charged impurities cause Coulomb scattering, which reduces mobility. Another mechanism is by improving the quality of the interface. For example, oxygen emitted from an MST film may provide oxygen to a Si—SiO₂ interface, reducing the presence of sub-stochastic SiOₓ. Alternately, the trapping of interstitials by MST layers may reduce the concentration of interstitial silicon proximate to the Si—SiO₂ interface, reducing the tendency to form sub-stochastic SiOₓ. Sub-stochastic SiOₓ at the Si—SiO₂ interface is known to exhibit inferior insulating properties relative to stochastic SiO₂. Reducing the amount of sub-stochastic SiOₓ at the interface more effectively confines free carriers (electrons or holes) in the silicon, and thus improves the mobility of these carriers due to electric fields applied parallel to the interface, as is standard practice in field effect transistor (“FET”) structures. Scattering due to the direct influence of the interface is called “surface-roughness scattering”, which may advantageously be reduced by the proximity of MST layers followed by anneals or during thermal oxidation.

In addition to the enhanced mobility characteristics of MST structures, they may also be formed or used in such a manner that they provide piezoelectric, pyroelectric, and/or ferroelectric properties that are advantageous for use in a variety of different types of devices, as discussed further in U.S. Pat. No. 7,517,702, which is also from the present Applicant and is hereby incorporated herein in its entirety by reference.

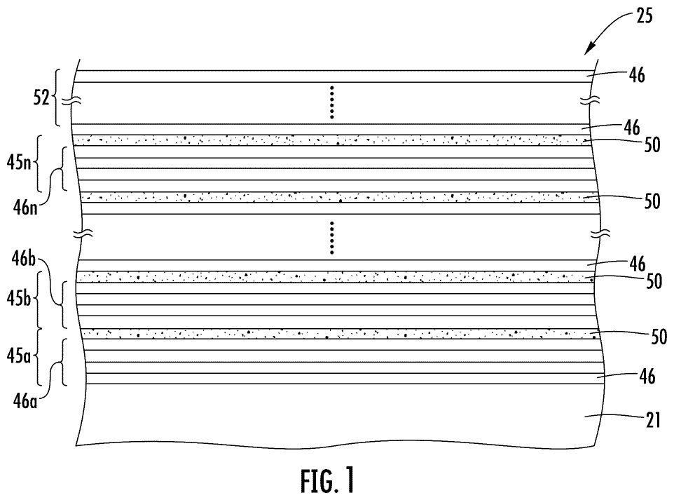

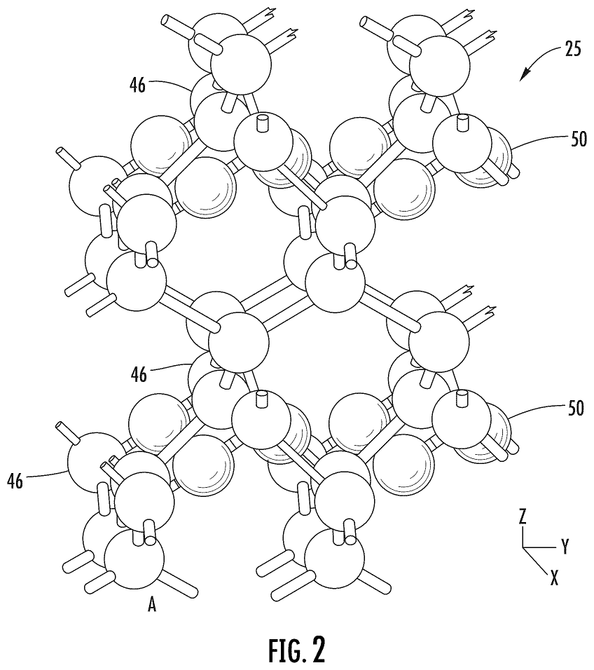

Referring now to FIGS. 1 and 2, the materials or structures are in the form of a superlattice 25 whose structure is controlled at the atomic or molecular level and may be formed using known techniques of atomic or molecular layer deposition. The superlattice 25 includes a plurality of layer groups 45a-45n arranged in stacked relation, as perhaps best understood with specific reference to the schematic cross-sectional view of FIG. 1.

Each group of layers 45a-45n of the superlattice 25 illustratively includes a plurality of stacked base semiconductor monolayers 46 defining a respective base semiconductor portion 46a-46n and a non-semiconductor monolayer(s) 50 thereon. The non-semiconductor monolayers 50 are indicated by stippling in FIG. 1 for clarity of illustration.

The non-semiconductor monolayer 50 illustratively includes one non-semiconductor monolayer constrained within a crystal lattice of adjacent base semiconductor portions. By “constrained within a crystal lattice of adjacent base semiconductor portions” it is meant that at least some semiconductor atoms from opposing base semiconductor portions 46a-46n are chemically bound together through the non-semiconductor monolayer 50 therebetween, as seen in FIG. 2. Generally speaking, this configuration is made possible by controlling the amount of non-semiconductor material that is deposited on semiconductor portions 46a-46n through atomic layer deposition techniques so that not all (i.e., less than full or 100% coverage) of the available semiconductor bonding sites are populated with bonds to non-semiconductor atoms, as will be discussed further below. Thus, as further monolayers 46 of semiconductor material are deposited on or over a non-semiconductor monolayer 50, the newly deposited semiconductor atoms will populate the remaining vacant bonding sites of the semiconductor atoms below the non-semiconductor monolayer.

In other embodiments, more than one such non-semiconductor monolayer may be possible. It should be noted that reference herein to a non-semiconductor or semiconductor monolayer means that the material used for the monolayer would be a non-semiconductor or semiconductor if formed in bulk. That is, a single monolayer of a material, such as silicon, may not necessarily exhibit the same properties that it would if formed in bulk or in a relatively thick layer, as will be appreciated by those skilled in the art.

Moreover, this superlattice structure may also advantageously act as a barrier to dopant and/or material diffusion between layers vertically above and below the superlattice 25. These properties may thus advantageously allow the superlattice 25 in one example implementation to provide an interface for high-K dielectrics which not only reduces diffusion of the high-K material into the channel region, but which may also advantageously reduce unwanted scattering effects and improve device mobility, as will be appreciated by those skilled in the art.

The superlattice 25 also illustratively includes a cap layer 52 on an upper layer group 45n. The cap layer 52 may comprise a plurality of base semiconductor monolayers 46. The cap layer 52 may have between 2 to 100 monolayers of the base semiconductor, and, more preferably between 10 to 50 monolayers.

Each base semiconductor portion 46a-46n may comprise a base semiconductor selected from the group consisting of Group IV semiconductors, Group III-V semiconductors, and Group II-VI semiconductors. Of course, the term Group IV semiconductors also includes Group IV-IV semiconductors, as will be appreciated by those skilled in the art. More particularly, the base semiconductor may comprise at least one of silicon and germanium, for example.

Each non-semiconductor monolayer 50 may comprise a non-semiconductor selected from the group consisting of oxygen, nitrogen, fluorine, carbon and carbon-oxygen, for example. The non-semiconductor is also desirably thermally stable through deposition of a next layer to thereby facilitate manufacturing. In other embodiments, the non-semiconductor may be another inorganic or organic element or compound that is compatible with the given semiconductor processing as will be appreciated by those skilled in the art.

It should be noted that the term monolayer is meant to include a single atomic layer and also a single molecular layer. It is also noted that the non-semiconductor monolayer 50 provided by a single monolayer is also meant to include a monolayer wherein not all of the possible sites are occupied (i.e., there is less than full or 100% coverage). For example, with particular reference to the atomic diagram of FIG. 2, a 4/1 repeating structure is illustrated for silicon as the base semiconductor material, and oxygen as the energy band-modifying material. Only half of the possible sites for oxygen are occupied in the illustrated example.

In other embodiments and/or with different materials this one-half occupation would not necessarily be the case as will be appreciated by those skilled in the art. Indeed it can be seen even in this schematic diagram, that individual atoms of oxygen in a given monolayer are not precisely aligned along a flat plane as will also be appreciated by those of skill in the art of atomic deposition. By way of example, a preferred occupation range is from about one-eighth to one-half of the possible oxygen sites being full, although other numbers may be used in certain embodiments.

Silicon and oxygen are currently widely used in conventional semiconductor processing, and, hence, manufacturers will be readily able to use these materials as described herein. Atomic or monolayer deposition is also now widely used. Accordingly, semiconductor devices incorporating the superlattice 25 in accordance with the invention may be readily adopted and implemented, as will be appreciated by those skilled in the art.

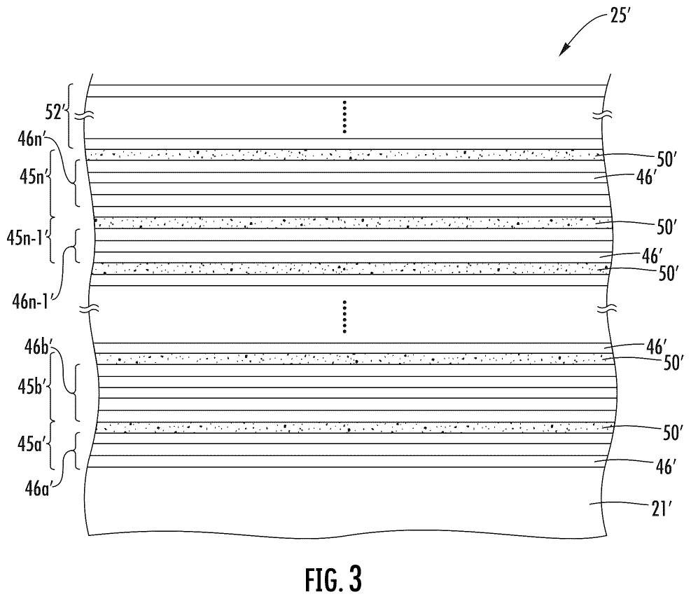

Referring now additionally to FIG. 3, another embodiment of a superlattice 25′ in accordance with the invention having different properties is now described. In this embodiment, a repeating pattern of 3/1/5/1 is illustrated. More particularly, the lowest base semiconductor portion 46a′ has three monolayers, and the second lowest base semiconductor portion 46b′ has five monolayers. This pattern repeats throughout the superlattice 25′. The non-semiconductor monolayers 50′ may each include a single monolayer. For such a superlattice 25′ including Si/O, the enhancement of charge carrier mobility is independent of orientation in the plane of the layers. Those other elements of FIG. 3 not specifically mentioned are similar to those discussed above with reference to FIG. 1 and need no further discussion herein.

In some device embodiments, all of the base semiconductor portions of a superlattice may be a same number of monolayers thick. In other embodiments, at least some of the base semiconductor portions may be a different number of monolayers thick. In still other embodiments, all of the base semiconductor portions may be a different number of monolayers thick.

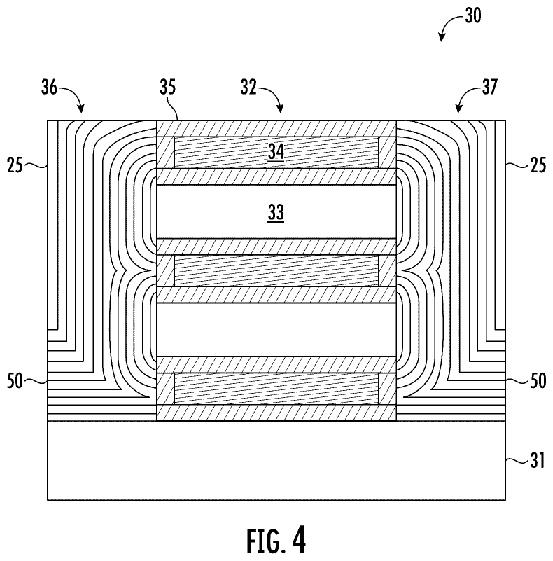

Turning now to FIG. 4, an example implementation in which the above-described MST films or superlattices 25 are utilized in the source and/or drain regions of a nanosheet transistor 30 is now described. More particularly, the nanosheet transistor 30 illustratively includes a vertical stack 32 of gate and nanostructure (here nanosheet) layers 33, with each gate layer including a gate electrode 34 (e.g., a metal electrode) and associated gate insulator 35. More particularly, multiple nanosheet layers 33 are stacked, each with a gate layer above and below, and the gate electrodes 34 are separated from the nanosheet layers and source/drain regions 36, 37 by the gate insulators 35. By way of example, the nanosheets 33 may be silicon, although other suitable semiconductors may be used in different embodiments. As used herein, “nanostructure” includes nanosheets as well as nanowires, as will be discussed further below.

Perpendicular to the cross-section illustrated in FIG. 4, there will be a depth dimension to the transistor 30 which is determined by lithography, depending on how much drive current is needed versus device area, as will be appreciated by those skilled in the art. The gate electrode 34 and gate insulator 35 may surround the edge of the device, although this may not be required in a nanosheet implementation. It should be noted that in other embodiments a nanowire configuration may be used instead of the illustrated nanosheet layers 33, which would have a similar cross-section but a reduced depth dimension. In such implementations the gate electrode 34 and gate insulator 35 may also surround the edge.

The MST layers 25 that fill the source and drain regions 36, 37 may advantageously trap dopants (e.g., phosphorus) throughout, helping to prevent the dopants from penetrating into the nanosheet layers 33. In this way, the nanosheets 33 may remain undoped, or other target amount of dopant may be more easily maintained therein, as appropriate for the particular implementation. More specifically, this would otherwise be challenging given the relatively high dopant concentrations to be utilized in the source and drain regions 36, 37.

The MST layers 25 are selectively formed, growing out from exposed silicon surfaces of the nanosheet layers 33, as well as the exposed silicon substrate (although other semiconductor materials may be used, as discussed further above). In this way, the non-semiconductor monolayers 50 of the superlattices 25 are arranged along growth rings extending laterally outwardly from respective ends of the nanosheets 33, as seen in FIG. 4. In some implementations, the substrate 31 may be separated from the source and drain regions 36, 37, e.g., by an additional insulator (SOI) layer, in which case the shape of the MST layers would be different, as will be appreciated by those skilled in the art.

Generally speaking, a single layer of MST film 25 will have a finite capacity to trap dopants (e.g., phosphorus), so filling all or substantially all of the source and drain regions 36, 37 allows for trapping of greater amounts of phosphorus. In practice, it may be desirable that the concentration of phosphorus is relatively high. For example, it may be as high as 1×10²¹/cm³ or more. This high concentration of phosphorus provides multiple technical advantages. On the one hand, it provides electrons to minimize the resistance of the source and drain regions 36, 37, as well as between the source and drain regions and the metal source/drain contacts (not shown). On the other hand, it also provides tensile strain, which reduces the conduction effective mass and increases electron velocity (and current).

By way of background, in typical nanosheet devices, phosphorus tends to diffuse into the nanosheet channel. To reduce this diffusion, a combination of an undoped buffer adjacent to the nanosheet, and/or an arsenic-doped layer between the phosphorus-doped source/drain regions and the nanosheet, may be used. Downsides of arsenic are that: (1) the peak available active concentration of arsenic is lower than can be attained with phosphorus; and (2) the arsenic fails to add tensile strain to the structure, yet tensile strain is beneficial for electron transport and may also reduce the Schottky barrier to the metal contact.

In this regard, Applicant theorizes without wishing to be bound thereto that the MST material in the above-described implementation may affect the Schottky barrier resistance between the source and drain regions 36, 37 and any metal (contact) on the top of the source and drain regions. In this regard, after planarization an additional MST layer 25 may be formed to help affect the Schottky barrier, if desired.

Generally speaking, the MST layers 25 which may have the most impact for the reduction or prevention of dopant (e.g., phosphorus) diffusion are those closest to the nanosheet layer 33 interface, and adjacent to the substrate 31 if diffusion of phosphorus into the substrate is a concern. In this regard, the source and drain regions 36, 37 need not necessarily be completely filled with MST layers 25 in all embodiments. The remaining volume may be filled with a large semiconductor cap layer 52, for example. Thus, in practice the entire source and drain regions may not be completely filled with MST layers 25 as shown in FIG. 4. However, the ultimate percentage of filling may be a matter of cost-benefit in terms of phosphorous retention capability vs. the additional deposition time taken to form more MST layers, as will be appreciated by those skilled in the art. Moreover, the number of layers used may depend on other factors such as device dimensions. For example, with regard to stability of ultra-small (in area) MST layers 25, more fully filling the source and drain regions 36, 37 with more MST layers 25 will help maximize the area of layers rather than relying on the smallest area layers immediately adjacent to the nanosheet layers 33.

Generally speaking, the dopant retention advantage increases with each additional MST layer that is used. The volume of the S/D regions that a given number of layers occupies will depend on the particular device. For example, for nanoscale devices, a thickness of MST layers equal to several diffusion lengths of the dopant material will fill most if not all of the S/D region, but for devices with larger S/D regions the total volume occupied by the same number of MST layers would be less.

Also, it is common practice to use an arsenic-doped layer in the S/D in combination with a phosphorus-doped layer. This is because the arsenic layer is more abrupt (less prone to diffusion), but has higher resistivity. The phosphorus layer further from the nanosheet is lower resistance, but more prone to diffusion. As such, the arsenic-doped layer acts as a buffer between the phosphorus-doped layer and the nanosheet. The use of MST layers in the S/D region may advantageously reduce or eliminate the need for this arsenic buffer in some embodiments. In other configurations, the MST layers may also be incorporated into the arsenic-doped layers. Example dopants include arsenic or phosphorus, using arsine or phosphine.

In addition to nanosheet and nanowire implementations, the foregoing approach may also be applied to FinFETs as well. In this regard, FinFETs may be considered nanosheets flipped onto their edges, while nanowires may be considered as relatively shallow nanosheets. Furthermore, various examples of FinFET devices are set forth in U.S. Pat. Nos. 7,202,494 and 10,580,867, which are also assigned to the present Applicant and hereby incorporated herein in their entireties by reference. Formation of these various structures may be performed by growing MST layers 25 in-situ doped with phosphorus, for example using PH₃ as a source gas. In an example implementation, a relatively high target concentration of phosphorus at or above 1×10²¹/cm³ may be used, as noted above.

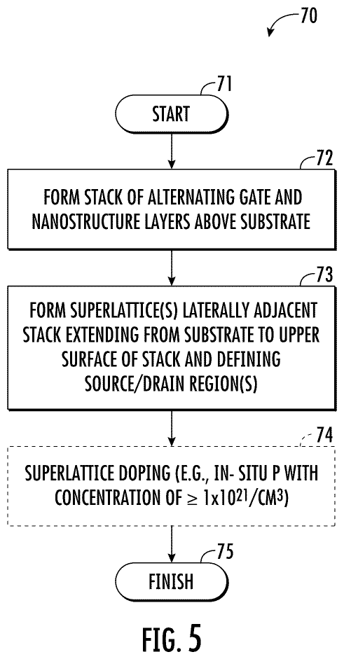

Turning now to the flow diagram 70 of FIG. 5, a method for making the semiconductor device 30 is now described. Beginning at Block 71, the method begins with forming the stack 32 of gate layers (including gate electrodes 34/gate insulators 35) and nanostructures 33, at Block 72. In the semiconductor device 30 of FIG. 4, these layers are formed one vertically on top of the next as shown.

The method of FIG. 5 further illustratively includes forming the source and drain superlattices 25 in the source and drain regions laterally adjacent the stack 32, as discussed further above. Moreover, these superlattices 25 may optionally be doped (including in-situ doping) to provide the technical discussed further above (Block 74), yet while helping prevent undesirable dopant creep into the nanosheets 33. The method of FIG. 5 illustratively concludes at Block 75.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that other modifications and embodiments are intended to be included within the scope of this disclosure.

1. A semiconductor device comprising:
a substrate;
a stack of alternating gate and nanostructure layers above the substrate; and
a first superlattice laterally adjacent the stack on a first side thereof and extending from the substrate to an upper surface of the stack to define a first source/drain region;
the first superlattice comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions;
the non-semiconductor monolayers of the first superlattice arranged along growth rings extending outwardly from respective adjacent nanostructure layer portions.

2. The semiconductor device of claim 1 further comprising a second superlattice laterally adjacent the stack on a second side thereof and extending from the substrate to the upper surface of the stack to define a second source/drain region, the second superlattice comprising a plurality of stacked groups of layers, each group of layers comprising a plurality of stacked base semiconductor monolayers defining a base semiconductor portion, and at least one non-semiconductor monolayer constrained within a crystal lattice of adjacent base silicon portions; and wherein the non-semiconductor monolayers of the second superlattice are arranged along growth rings extending outwardly from respective adjacent nanostructure layer portions.

3. The semiconductor device of claim 2 wherein the first and second source/drain regions define respective channels for the semiconductor device through the nanostructure layers.

4. The semiconductor device of claim 1 wherein the alternating gate and nanostructure layers are vertically stacked above the substrate.

5. The semiconductor device of claim 1 wherein the nanostructure layers comprise nanosheets.

6. The semiconductor device of claim 1 wherein each gate layer comprises:
a gate electrode; and
a gate insulator separating the gate electrode from adjacent nanostructure layers.

7. The semiconductor device of claim 1 wherein the first source/drain region comprises a phosphorous dopant.

8. The semiconductor device of claim 1 wherein the first source/drain region has a dopant concentration of at least 1×10²¹/cm³.

9. The semiconductor device of claim 1 wherein the base semiconductor monolayers comprise silicon.

10. The semiconductor device of claim 1 wherein the non-semiconductor monolayers comprise oxygen.

11. A semiconductor device comprising:
a substrate;
a stack of alternating gate and nanosheet layers above the substrate;
a first superlattice laterally adjacent the stack on a first side thereof and extending from the substrate to an upper surface of the stack to define a first source/drain region; and
a second superlattice laterally adjacent the stack on a second side thereof and extending from the substrate to the upper surface of the stack to define a second source/drain region;
the first and second superlattices each comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions;
the non-semiconductor monolayers of the first and second superlattices arranged along growth rings extending outwardly from respective adjacent nanosheet layer portions.

12. The semiconductor device of claim 11 wherein the first and second source/drain regions define respective channels for the semiconductor device through the nanosheet layers.

13. The semiconductor device of claim 11 wherein the alternating gate and nanostructure layers are vertically stacked above the substrate.

14. The semiconductor device of claim 11 wherein each gate layer comprises:
a gate electrode; and
a gate insulator separating the gate electrode from adjacent nanostructure layers.

15. The semiconductor device of claim 11 wherein the first source/drain region comprises a phosphorous dopant.

16. The semiconductor device of claim 11 wherein the first source/drain region has a dopant concentration of at least 1×10²¹/cm³.

17. A semiconductor device comprising:
a substrate;
a stack of alternating gate and nanostructure layers above the substrate; and
a first superlattice laterally adjacent the stack on a first side thereof and extending from the substrate to an upper surface of the stack to define a first source/drain region;
the first superlattice comprising a plurality of stacked groups of layers, each group of layers comprising a plurality of stacked base silicon monolayers defining a base silicon portion, and at least one oxygen monolayer constrained within a crystal lattice of adjacent base silicon portions;
the oxygen monolayers of the first superlattice arranged along growth rings extending outwardly from respective adjacent nanostructure layer portions.

18. The semiconductor device of claim 17 further comprising a second superlattice laterally adjacent the stack on a second side thereof and extending from the substrate to the upper surface of the stack to define a second source/drain region, the second superlattice comprising a plurality of stacked groups of layers, each group of layers comprising a plurality of stacked base silicon monolayers defining a base silicon portion, and at least one oxygen monolayer constrained within a crystal lattice of adjacent base silicon portions; and wherein the oxygen monolayers of the second superlattice are arranged along growth rings extending outwardly from respective adjacent nanostructure layer portions.

19. The semiconductor device of claim 18 wherein the first and second source/drain regions define respective channels for the semiconductor device through the nanostructure layers.

20. The semiconductor device of claim 17 wherein the alternating gate and nanostructure layers are vertically stacked above the substrate.
